(19) United States
(12) Patent Application Publication
(10) Pub. No.: US 2009/0257196 A1
(43) Pub. Date: Oct. 15, 2009

(54) Methods and Apparatus for Heat Transfer for a Component

(75) Inventors: James E. Faoro, Tucso, AZ (US); James R. Myers, Tucson, AZ (US); Isis Roche-Rios, Tucson, AZ (US); Steven N. Peterson, Tucson, AZ (US); Cynthia R. Konen, Anoka, MN (US); George R. Cunnington, Oro Valley, AZ (US); Kevin A. Paulson, Salt Lake City, UT (US)

Correspondence Address: Ingrassia Fisher & Lorenz, P.C. (Raytheon), 7010 East Cochise Road, Scottsdale, AZ, 85253-1406, US

(73) Assignee: Raytheon Company

(21) Appl. No.: 12/363,240

(22) Filed: Jan. 30, 2009

Related U.S. Application Data
(60) Provisional application No. 61/025,248, filed on Jan. 31, 2008.

(51) Int. Cl. H05K 7/20

(52) U.S. Cl. 361/719

(57) ABSTRACT

Methods and apparatus for transferring heat according to various aspects of the present invention operate in conjunction with a heat source on a substrate. In one embodiment, a lid is adapted to engage the substrate. The lid may comprise a thermally conductive rigid body and one or more hardstops configured to limit a bond line distance between the rigid body and the heat source. A thermal interface material may be disposed in the bond line between the heat source and the lid. The thermal interface material may be adapted to provide a thermally conductive adhesive bond between the lid and the heat source.

### CROSS-REFERENCE TO RELATED APPLICATIONS

This application claims the benefit of U.S. Provisional Patent Application No. 61/025,248, filed on Jan. 31, 2008, and incorporates the disclosure of the application by reference.

### GOVERNMENT LICENSE RIGHTS

This invention was made with United States Government support under Contract Number HQ006-01-C-00. The United States Government has certain rights in this invention.

### BACKGROUND OF THE INVENTION

Thermal management of an integrated circuit (IC) is important for the proper operation and reliability of the component. The ever reducing size of integrated circuits such as microprocessors presents a problem for thermal management as more power is passed through smaller and smaller chips. Traditional methods of cooling involve attaching a heat sink to the die of a chip to dissipate the heat produced on the surface of the die. Other methods have used fans to facilitate the movement of air across the chip surface or the heat sink.

Thermally conductive materials have been used to fill the gap between the chip and the heat sink in an attempt to enhance heat dissipation. This has met with limited success. Research has shown that the interface between the chip and the method of cooling are affected by factors such as the gap between the surfaces, and the type of materials used.

### SUMMARY OF THE INVENTION

Methods and apparatus for transferring heat according to various aspects of the present invention operate in conjunction with a heat source on a substrate. In one embodiment, a lid is adapted to engage the substrate. The lid may comprise a thermally conductive rigid body and one or more hardstops configured to limit a bond line distance between the rigid body and the heat source. A thermal interface material may be disposed in the bond line between the heat source and the lid. The thermal interface material may be adapted to provide a thermally conductive adhesive bond between the lid and the heat source.

### BRIEF DESCRIPTION OF THE DRAWINGS

A more complete understanding of the present invention may be derived by referring to the detailed description and claims when considered in connection with the following illustrative figures. In the following figures, like reference numbers may refer to similar elements and steps.

FIG. 1 representatively illustrates an integrated circuit installed on a circuit board in accordance with an exemplary embodiment of the present invention;

FIG. 2 representatively illustrates a thermally conductive lid in accordance with an exemplary embodiment of the present invention; and

FIG. 3 representatively illustrates a cross section of the interface between the thermally conductive lid and the integrated circuit.

Elements and steps in the figures are illustrated for simplicity and clarity and have not necessarily been rendered according to any particular sequence. For example, steps that may be performed concurrently or in different order are illustrated in the figures to help to improve understanding of embodiments of the present invention.

### DETAILED DESCRIPTION OF EXEMPLARY EMBODIMENTS

The present invention is described partly in terms of functional components, methods, and objectives. Such functional components and methods may be realized by any number of components, systems, and/or methods configured to perform the specified functions and achieve the various results. For example, the present invention may employ various thermally conductive materials, heat sources, heat sinks, body shapes, sizes, and weights for various components, such as thermal interface materials, heat exchangers, mechanical components, and the like, which may carry out a variety of functions. In addition, the present invention may be practiced in conjunction with any number of applications and environments, and the systems described are merely exemplary applications of the invention. Further, the present invention may employ any number of conventional techniques for manufacture, installation, and the like.

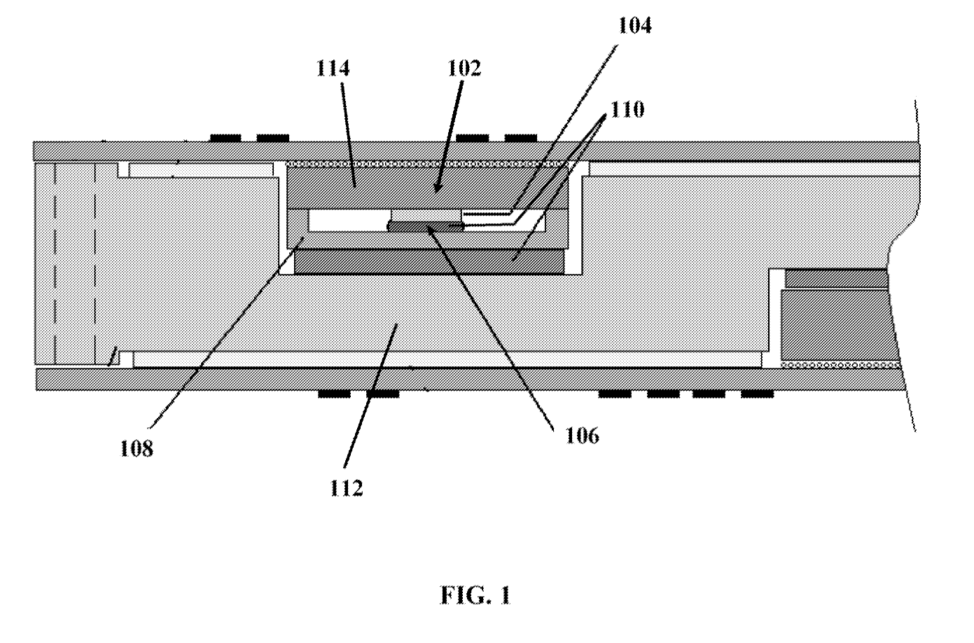

Referring to FIG. 1, exemplary methods and apparatus for transferring heat from a heat source to a heat sink according to various aspects of the present invention operate in conjunction with an integrated circuit. Referring now to FIG. 1, a thermally conductive lid 108 may transfer heat generated by the integrated circuit 102 to a heat sink 112. The heat sink 112 disposes of heat, such as via transfer to the surrounding environment or to a cooling system. A thin bond line 106 fills the region between the thermally conductive lid 108 and the integrated circuit 102. The bond line 106 may be filled with a thermally conductive interface material 110 to transfer heat from the integrated circuit 102 to the thermally conductive lid 108.

The integrated circuit 102 may comprise any integrated circuit or similar system requiring cooling during operation. For example, the integrated circuit 102 may comprise a microchip, such as microprocessor. In the present embodiment, the integrated circuit 102 comprises a microprocessor with a silicon die 104 that has significantly less surface area than its corresponding substrate 114. Examples of representative microprocessors include the IBM 750 FX and the Xilinx V2 Pro.

The thermally conductive lid 108 conductively transfers heat from the integrated circuit 102 to the heat sink 112. In addition, the thermally conductive lid 108 may define one or more walls of a package around the die 104. The thermally conductive lid 108 may comprise any suitable component for absorbing heat from the integrated circuit 102. For example, the thermally conductive lid 108 may include one or more surfaces capable of absorbing heat from a heat source. The thermally conductive lid 108 may further be sized substantially equal to the dimensions of the substrate 114 and larger than the size of the silicone die 104, such as to increase the surface area capable of transferring heat away from the integrated circuit 102. For example, in one embodiment, the increase in surface area of the thermally conductive lid 108 is approximately ten times the surface area of the die 104.

The thermally conductive lid 108 may be configured from any suitable thermally conductive material, such as aluminum, copper, or beryllium. The thermally conductive lid 108 may also be thin walled to increase the rate of heat transfer through the thermally conductive lid 108. For example, in one embodiment, the thermally conductive lid 108 comprises an aluminum heat spreader less than 0.06 inches thick having approximately the same overall dimensions as the substrate 114 of the integrated circuit 102.

As the thermally conductive lid 108 is reduced in thickness, its rigidity may become compromised to the extent that stiffeners may be required. A stiffener may comprise any system for maintaining rigidity such that a force or stress load applied to the thermally conductive lid 108 does not result in excessive deflections or deformations to the thermally conductive lid 108. For example, a stiffening bar may be added to a surface of the thermally conductive lid 108 such that a force applied to the center of the thermally conductive lid 108 is transferred to the edges of the thermally conductive lid 108.

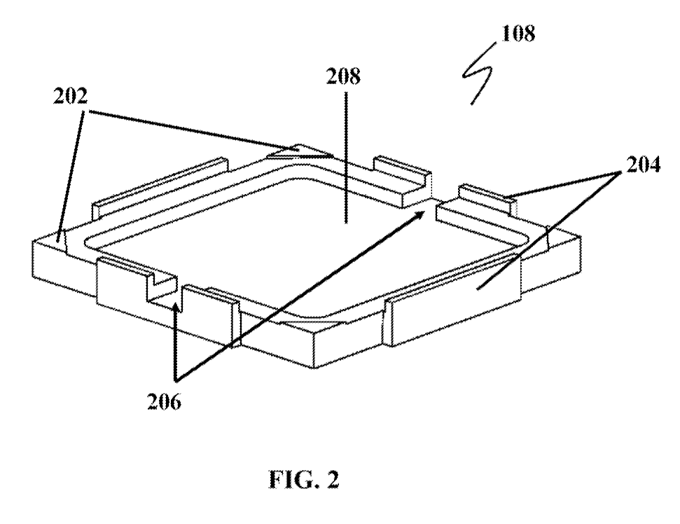

Referring now to FIG. 2, the thermally conductive lid 108 may also comprise several mechanical hardstops 202, alignment guides 204, and/or vents 206 set into the thermally conductive lid 108. The hardstops 202 inhibit the thermally conductive lid 108 from coming into direct contact with the die 104 to reduce the likelihood of damage to the die 104. The hardstops 202 also direct any forces applied to the heat sink 112 or thermally conductive lid 108 away from the die 104 and onto the substrate 114 of the integrated circuit 102.

The hardstops 202 may comprise any system for maintaining a slight gap between the thermally conductive lid 108 and the die 104. For example, the hardstops 202 may comprise platforms, ridges, steps, or the like and may be affixed or connected to the thermally conductive lid 108. Alternatively, the hardstops 202 may be machined or cast into a surface of the thermally conductive lid 108. In the present embodiment, the hardstops 202 comprise multiple raised standoffs positioned at the corners of a surface on the thermally conductive lid 108. The raised standoffs are further configured to be positioned against the substrate 114 when the thermally conductive lid 108 is installed. The hardstops 202 may further be configured to control the thickness of the bond line 106 gap between the die 104 and a conductive surface 208 of the thermally conductive lid 108. For example, in one embodiment, the bond line 106 may comprise a distance of between three to ten thousandths of an inch. The hardstops 202 help account for tolerance variations inherent to the integrated circuit 102 manufacturing process while maintaining a maximum bond line 106 gap for efficient heat conductivity between the die 104 and the thermally conductive lid 108.

The alignment guides 204 tend to ensure proper placement of the conductive surface 208 of the thermally conductive lid 108 over the heat source during installation. Proper positioning of the thermally conductive lid 108 may be achieved by any suitable method or alignment guide 204, such as alignment markers, keyed notches, or the like. In the present embodiment, the alignment guides 204 comprise a series of shelves set around the perimeter of thermally conductive lid 108. In one embodiment, the protrusions or shelves may be located along the sides of the thermally conductive lid 108. In an alternative embodiment, the shelves comprise two protrusions set near each corner of the thermally conductive lid 108. The protrusions tend to align the thermally conductive lid 108 around the integrated circuit 102 during installation and keep the thermally conductive lid 108 in place while the thermally conductive interface material 110 cures.

The vent 206 provides a passage for ambient air to enter and circulate around the heat source providing additional cooling capacity. The vent 206 may comprise any system for allowing air to enter under thermally conductive lid 108. In the present embodiment, the vent 206 comprises a pair of notches in opposite sides of thermally conductive lid 108. In an alternative embodiment, the vent 206 may comprise one or more holes placed in the thermally conductive lid 108 or a series of gaps between the alignment guides 204.

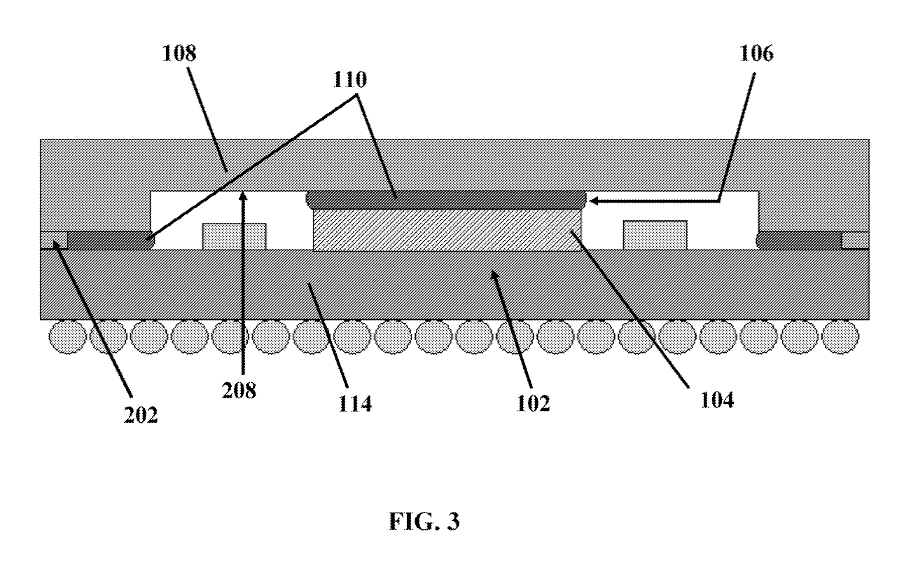

Referring now to FIG. 3, the thermal interface material 110 may provide a thermally conductive bond between the thermally conductive lid 108 and the integrated circuit 102. In the present embodiment, the thermal interface material 110 fills the bond line 106 between the die 104 and the thermally conductive lid 108. The thermal interface material may comprise any system for adhesively bonding the thermally conductive lid 108 to the integrated circuit 102 while also providing a conductive path for heat transfer from the die 104 to the conductive surface 208 of the thermally conductive lid 108. The thermal interface material 110 may also be used to bond the thermally conductive lid 108 to the substrate 114 portion of the integrated circuit 102.

The thermal interface material 110 may comprise any suitable material, such as a room temperature vulcanizing (RTV) silicone adhesive or curable putty. In a representative embodiment, the RTV silicone may comprise additional additives to enhance thermal conductivity. Examples of such additives include alumina, aluminum oxide, alumina and methyl silicone, and aluminum chromate. The thermal interface material 110 may also be applied by various methods, such as manual application, machine placement, and/or spraying. In one embodiment, the thermal interface material 110 may be applied, such as with the aid of a stenciling tool, to inhibit the thermal interface material 110 from filling the air gap between the thermally conductive lid 108 and the substrate 114 of the integrated circuit 102. Application of the thermal interface material 110 in this manner limits the placement of the thermal interface material 110 to the top of the die 104 and localized areas of the substrate 114.

Thermal conductivity of the thermal interface material 110 may be selected according to the amount of heat to be dissipated from the integrated circuit 102. For example, high power microprocessors may require heat dissipation of more than eight watts. In the present embodiment, the thermal interface material 110 may provide a thermal conductivity of at least 1.0 watt/meter ° K. between the die 104 and the conductive surface 208 of the thermally conductive lid 108.

In addition to bonding the thermally conductive lid 108 to the die 104 and providing thermal conductivity, the thermal interface material 110 may be selected and/or adapted for use in multiple environments, such as to maintain a desired elasticity across wide temperature ranges, over time, and environments. In one embodiment, the thermal interface material 110 may be exposed to predominantly cold temperatures during operation. In another embodiment, the thermal interface material 110 may operate in both cold and hot temperatures, such as a space-based installation. In the present embodiment, the thermal interface material 110 is suitably adapted to operate when exposed to temperatures of between −54° C. and +125° C. and have a useful life of at least ten years without becoming brittle, such a silicone RTV or a non-reactive silicone grease. In another embodiment, the thermal interface material 110 may be exposed to temperatures below −100° C. For such applications, the thermal interface material 110 may comprise RTV compounds with additives similar to those discussed above, which remain relatively resilient and pliable at such temperatures.

The bond strength of the thermal interface material 110 may also be selected according to anticipated types and degrees of stress loading, such as compressive or shear stresses. For example, in a spaced-based application, the thermal interface material 110 may undergo launch conditions where stresses induced from booster rockets impart significant deflective forces to the circuit card on which the integrated circuit 102 may be installed. In one representative embodiment, the thermal interface material 110 may require a shear strength of fifty to ninety pounds per square inch. In another embodiment, a shear strength of ten to fifty pounds per square inch may be required, while in a third embodiment a shear strength of fifty to three hundred pounds per square inch may be required. Materials, such as those discussed above, may provide the appropriate shear strengths for these conditions.

Another example of stress loading on the thermal interface material 110 may result from the coefficient of thermal expansion (CTE) mismatch between the substrate 114, the die 104, the thermally conductive lid 108, and the thermal interface material 110. The greater the difference in CTE between the various materials, the greater the stress loading on the materials as temperatures vary. One result of CTE mismatch could cause the die 104 to be pulled from the surface of the integrated circuit 102. Alternatively, the die 104 may separate from the thermally conductive lid 108. In the present embodiment, the thermal interface material 110 may have a CTE between 400 and 500 parts per million per degree Celsius. In another embodiment, the thermal interface material may have a CTE of less than 400 parts per million per degree Celsius. Various materials, such as RTV compounds with alumina, aluminum oxide and aluminum chromate additives, may provide the appropriate CTE for these conditions.

The thermal interface material 110 may also have a low rate of outgassing. In some embodiments, the thermal interface material 110 may operate in conditions where the vapor transmission or outgassing of materials must be strictly controlled or eliminated, such as space-based applications where condensation must be avoided. For example, materials with outgassing rates of less than 1% total mass loss and 0.1% collected volatile condensable mass may be required to prevent decreases in performance of other components.

Referring again to FIG. 1, the heat sink 112 absorbs heat from the thermally conductive lid 108 and dissipates that heat to the ambient environment. The heat sink 112 may comprise any system to absorb heat from the thermally conductive lid 108 such as a block of metal, a thermally conductive surface with multiple fins, or a coldplate. In the present embodiment, the heat sink 112 comprises a metallic block placed above the thermally conductive lid 108 and affixed to the circuit card assembly.

The heat sink 112 may have a much greater surface area than the integrated circuit 102 and/or the thermally conductive lid 108, resulting in a higher rate of heat dissipation relative to the thermally conductive lid 108. Due to the greater heat dissipation capability, the distance between the heat sink 112 and the thermally conductive lid 108 requires less control than the bond line 106 between the thermally conductive lid 108 and the die 104: The increased rate of heat dissipation by the heat sink 112 also reduces the need for as highly a conductive thermal adhesive between the heat sink 112 and the thermally conductive lid 108 as compared to the bond line 106 between the die 104 and the thermally conductive lid 108. As a result, a thermally conductive adhesive with less than a thermal conductivity of 1.0 watt/meter ° K. may be used.

In operation, the integrated circuit 102 is installed on a circuit card assembly (CCA). During final assembly of the CCA, the thermally conductive lid 108 may be installed over the integrated circuit 102 such that the bond line 106 between the die 104 and the thermally conductive lid 108 is minimized to the extent possible. Prior to placing the thermally conductive lid 108 over the die 104, the thermal interface material 110 may be applied to the thermally conductive lid 108. For example, the thermal interface material 110 may be applied with a stenciling tool to prevent the thermal interface material 110 from being placed on the hardstops 202 or in an area that would fill the gap between the substrate 114 and the thermally conductive lid 108.

Alignment guides 204 on the thermally conductive lid 108 align the conductive surface 208 over the die 104. The alignment guides 204 also hold the thermally conductive lid 108 in place while the thermal interface material 110 cures. In addition, the hardstops 202 maintain the bond line 106 gap between the die 104 and the lid 108. A thermally conductive adhesive may be either applied to the exposed surface of the thermally conductive lid 108 or to a heat sink 112. This adhesive may or may not be the same as that used between the thermally conductive lid 108 and the die 104. After the application of the adhesive, the heat sink 112 may be affixed above the thermally conductive lid 108, completing the installation.

During use, heat generated by the integrated circuit 102 is dissipated from the surface of the die 104 through the thermal interface material 110 to the conductive surface 208 of the thermally conductive lid 108. The heat in the thermally conductive lid 108 is then conducted to the heat sink 112. The heat sink 112 then dissipates the heat to the ambient air.

In the foregoing specification, the invention has been described with reference to specific exemplary embodiments. Various modifications and changes may be made, however, without departing from the scope of the present invention as set forth in the claims. The specification and figures are illustrative, rather than restrictive, and modifications are intended to be included within the scope of the present invention. Accordingly, the scope of the invention should be determined by the claims and their legal equivalents rather than by merely the examples described.

For example, the steps recited in any method or process claims may be executed in any order and are not limited to the specific order presented in the claims. Additionally, the components and/or elements recited in any apparatus claims may be assembled or otherwise operationally configured in a variety of permutations and are accordingly not limited to the specific configuration recited in the claims.

Benefits, other advantages and solutions to problems have been described above with regard to particular embodiments; however, any benefit, advantage, solution to problem or any element that may cause any particular benefit, advantage or solution to occur or to become more pronounced are not to be construed as critical, required or essential features or components of any or all the claims.

The terms “comprise”, “comprises”, “comprising”, “having”, “including”, “includes” or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

1. A heat transfer device for a heat source on a substrate, comprising:
a lid configured to engage the substrate, comprising:
a thermally conductive rigid body; and
a plurality of hardstops configured to limit a bond line distance between the rigid body and the heat source; and
a thermal interface material disposed in the bond line between the heat source and the lid, wherein the thermal interface material is adapted to provide a thermally conductive adhesive bond between the lid and the beat source.

2. A heat transfer device according to claim 1, wherein the lid is less than 0.06 inches thick.

3. A heat transfer device according to claim 1, wherein the thermal interface material is further adapted to remain non-rigid and non-brittle over a period of at least ten years.

4. A heat transfer device according to claim 3, wherein the thermal interface material comprises an alumina-oxide filled room temperature vulcanizing silicone.

5. A heat transfer device according to claim 3, wherein the thermal interface material has a rate of outgassing less than 1% total mass loss and 0.1% collected volatile condensable mass.

6. A heat transfer device according to claim 1, wherein the lid further comprises an alignment guide configured to position the lid about the heat source.

7. A heat transfer device according to claim 1, further comprising a vent in the lid, wherein the vent is configured to allow air to circulate around the heat source.

8. A heat transfer device according to claim 1, wherein the lid further comprises stiffeners configured to reduce deflections resulting from stress loads applied to the lid.

9. A heat transfer device according to claim 1, further comprising:
a heat sink, wherein the heat sink engages the opposite side of the lid as the heat source; and
a second thermal interface material disposed between the lid and the heat sink.

10. A heat transfer device for an integrated circuit comprising a die and a substrate, comprising:
a lid configured to engage the integrated circuit, comprising:
a thermally conductive body with substantially the same area as the integrated circuit, wherein the thermally conductive body is adapted to absorb heat from the die; and
a plurality of hardstops configured to:
be positioned on the surface of the substrate;
prevent direct contact between the thermally conductive body and the die; and
limit a bond line distance between the thermally conductive body and the die; and
a thermal interface material located between the integrated circuit and the lid, wherein the thermal interface material is adapted to provide thermally conductive adhesive bond between the lid and the integrated circuit.

11. A heat transfer device according to claim 10, wherein the lid is less than 0.06 inches thick.

12. A heat transfer device according to claim 10, wherein the thermal interface material is further adapted to remain non-rigid and non-brittle over a period of at least ten years.

13. A heat transfer device according to claim 12, wherein the thermal interface material comprises an alumina-oxide filled room temperature vulcanizing silicone.

14. A heat transfer device according to claim 12, wherein the thermal interface material has a rate of outgassing less than 1% total mass loss and 0.1% collected volatile condensable mass.

15. A heat transfer device according to claim 10, wherein the lid further comprises an alignment guide configured to position the lid about the integrated circuit.

16. A heat transfer device according to claim 10, further comprising a vent in the lid, wherein the vent is configured to allow air to circulate between the lid and the substrate.

17. A heat transfer device according to claim 10, wherein the lid further comprises stiffeners configured to reduce deflections resulting from stress loads applied to the lid.

18. A heat transfer device according to claim 10, further comprising:
a heat sink, wherein the heat sink engages the opposite side of the lid as the silicone die; and
a second thermal interface material located between the lid and the heat sink, wherein the second thermal interface material is adapted to provide a thermally conductive adhesive bond between the lid and the heat sink.

19. A method for cooling an integrated circuit with a die, comprising:
securing a thermally conductive lid comprising a hardstop to the surface of the integrated circuit with a first thermally conductive adhesive material, wherein:
the hardstop is configured to limit a bond line distance between the thermally conductive lid and the die, and
the first thermally conductive material comprises an aluminum oxide filled room temperature vulcanizing silicone; and
affixing a heat sink to the thermally conductive lid with a second thermally conductive adhesive material.

20. A method for cooling an integrated circuit according to claim 19, wherein the thermally conductive lid further comprises:
a plurality of alignment guides configured to position the thermally conductive lid about the integrated circuit; and
a vent configured to allow air to circulate between the thermally conductive lid and the integrated circuit.
